(19) United States
(12) Patent Application Publication
(10) Pub. No.: US 2026/0075708 A1
(43) Pub. Date: Mar. 12, 2026

(54) ELECTRONIC DEVICE AND MANUFACTURING METHOD OF THE SAME

(71) Applicant: AUO Corporation, Hsinchu City (TW)

(72) Inventor: Hsin Hua Tsai, Hsinchu City (TW)

(73) Assignee: AUO Corporation, Hsinchu City (TW)

(21) Appl. No.: 18/950,203

(22) Filed: Nov. 18, 2024

(30) Foreign Application Priority Data
Sep. 12, 2024 (TW) 113134728

(51) Int. Cl. H05K 1/02; G03F 7/00; H05K 3/02; H05K 3/46

(52) U.S. Cl. CPC H05K 1/0296; G03F 7/0035; H05K 3/02; H05K 3/4644

(57) ABSTRACT

An electronic device including a substrate, an insulating layer, and a conductive layer, which are sequentially stacked, is provided. The insulating layer includes a first portion, a second portion, and a third portion. The second portion is located on a side of the first portion away from the conductive layer, and the third portion is located on a side of the second portion away from the conductive layer. The first portion, the second portion, and the third portion are sited in a connection manner. A top surface of the conductive layer away from the substrate is higher than a top surface of the insulating layer. Top surfaces of the first portion and the third portion are higher than a top surface of the second portion. A manufacturing method of the electronic device is also provided.

### CROSS-REFERENCE TO RELATED APPLICATION

This application claims the priority benefit of Taiwan application serial no. 113134728, filed on Sep. 12, 2024. The entirety of the above-mentioned patent application is hereby incorporated by reference herein and made a part of this specification.

### BACKGROUND

### Technical Field

The disclosure relates to an electronic device and a manufacturing method of the same.

### Description of Related Art

In a manufacturing method of a conventional electronic device, only a single yellow light process phase is used to process a lamination structure. Due to low coverage of photoresist at some specific positions, wire breakage may occur. Although the above issue may be solved using two yellow light process phases, for more complex processing patterns, a patterned photoresist layer may be subject to water vapor intrusion and peeling, reducing integrity of a patterned conductive layer formed in a subsequent process, and ultimately leading to wire breakage in the electronic device.

### SUMMARY

The disclosure provides an electronic device and a manufacturing method of the same, which effectively avoids an issue of peeling of a photoresist layer during a manufacturing process and improves a yield of the electronic device.

According to an embodiment of the disclosure, an electronic device is provided, including a substrate, an insulating layer, and a conductive layer that are sequentially stacked. The insulating layer includes a first portion, a second portion, and a third portion. The second portion is located on a side of the first portion away from the conductive layer, and the third portion is located on a side of the second portion away from the conductive layer. The first portion, the second portion, and the third portion are sited in a connection manner. A top surface of the conductive layer away from the substrate is higher than a top surface of the insulating layer. A top surface of the first portion is higher than a top surface of the second portion, and a top surface of the third portion is higher than the top surface of the second portion.

According to another embodiment of the disclosure, a manufacturing method of an electronic device is provided, including the following. An insulating layer and a conductive layer are sequentially stacked on a substrate. A first patterned photoresist layer is formed using a first photomask. Corresponding to a pattern of the first patterned photoresist layer, a portion of the conductive layer is removed to expose the insulating layer. A second patterned photoresist layer is formed using a second photomask. The second patterned photoresist layer exposes a portion of the insulating layer. The portion of the insulating layer is removed.

Based on the above, in the manufacturing method of the electronic device provided in the embodiment of the disclosure, the electronic device is manufactured using two yellow light process phases, and a shape of the patterned photoresist layer is improved, so as to avoid the issues of peeling of the photoresist layer and wire breakage, greatly improving the yield of the electronic device.

In order for the aforementioned features and advantages of the disclosure to be more comprehensible, embodiments accompanied with drawings are described in detail below.

### BRIEF DESCRIPTION OF THE DRAWINGS

FIGS. 1A to 1F are schematic views of a manufacturing method of an electronic device according to an embodiment of the disclosure.

FIG. 1G is a schematic view of a photomask in a photolithography process shown in FIG. 1A.

FIG. 1H is a schematic view of a photomask in a photolithography process shown in FIG. 1D.

FIGS. 2A to 2F are schematic views of a manufacturing method of an electronic device according to a comparative example.

FIG. 2G is a schematic view of a photomask in a photolithography process shown in FIG. 2A.

FIG. 2H is a schematic view of a photomask in a photolithography process shown in FIG. 2D.

### DETAILED DESCRIPTION OF DISCLOSED EMBODIMENTS

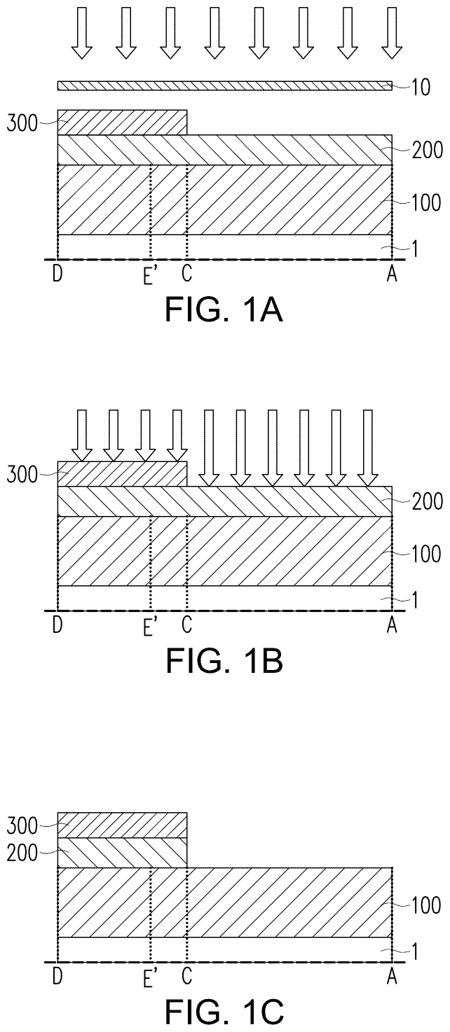

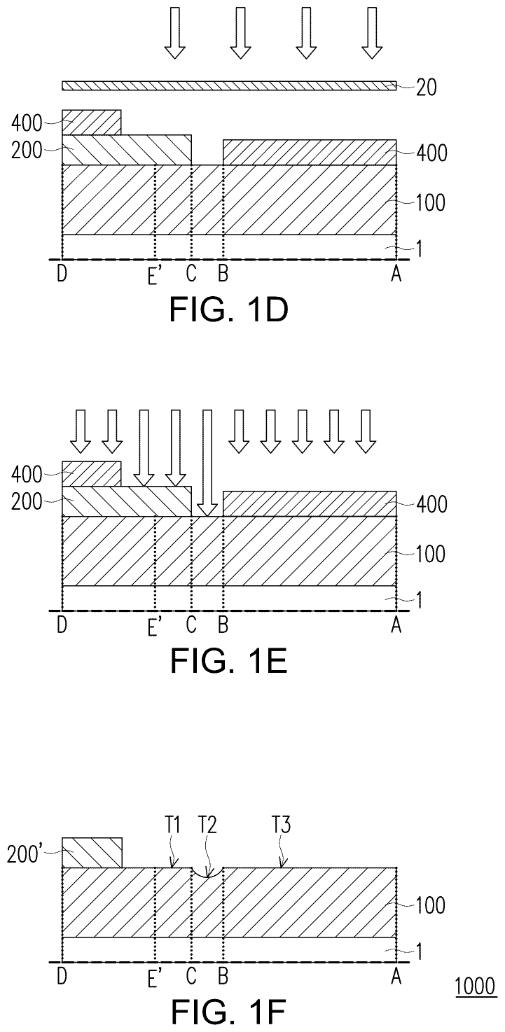

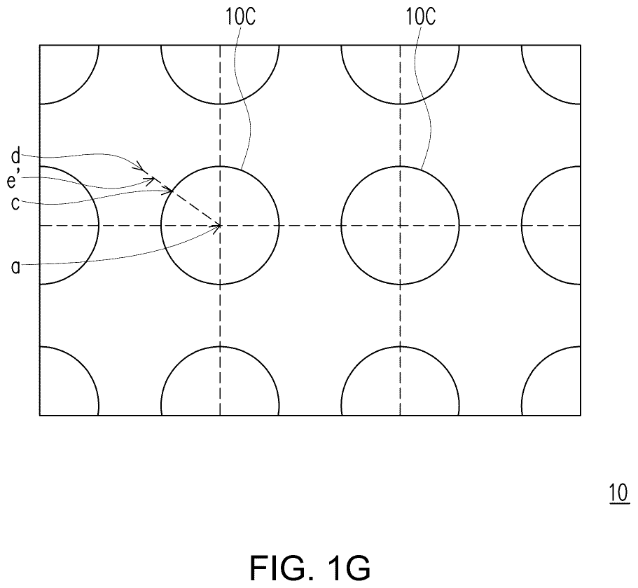

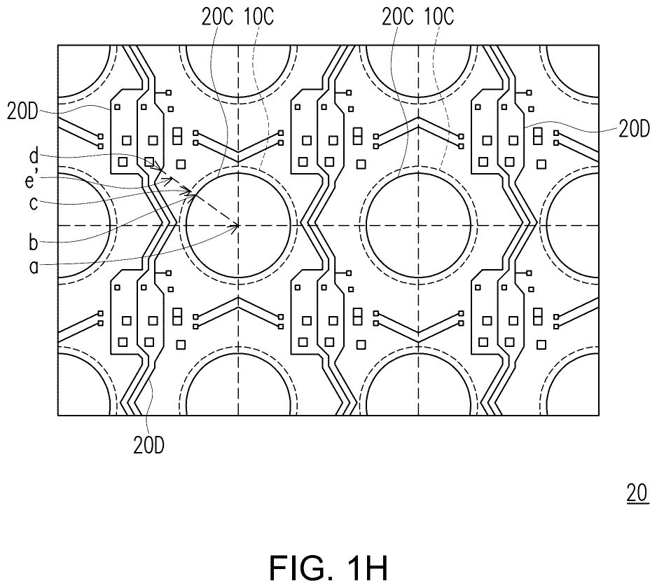

FIGS. 1A to 1F are schematic views of a manufacturing method of an electronic device according to an embodiment of the disclosure. For the convenience of understanding, FIGS. 1A to 1F only show partial cross-sectional views during a manufacturing process. Steps shown in FIGS. 1A to 1C are a yellow light process in a first phase, and steps shown in FIGS. 1D to 1F are the yellow light process in a second phase. FIG. 1G is a schematic view of a photomask in a photolithography process shown in FIG. 1A. A cross-section line AD in FIG. 1A is a straight line formed by three line segments of a line segment AC, a line segment CE′, and a line segment E′D. FIG. 1G shows a dashed line corresponding to the cross-section line AD in FIG. 1A, and positions a, c, e′, and d respectively corresponding to endpoints A, C, E′, and D of the line segments in FIG. 1A are correspondingly marked thereon. FIG. 1H is a schematic view of a photomask in a photolithography process shown in FIG. 1D. The cross-section line AD in FIG. 1D is a straight line formed by four line segments of a line segment AB, a line segment BC, the line segment CE′, and the line segment E′D. FIG. 1H shows a dashed line corresponding to the cross-section line AD in FIG. 1D, and the positions a, c, e′, and d corresponding to the endpoints A, C, E′, and D of the line segments in FIG. 1D are correspondingly marked thereon.

In the step shown in FIG. 1A, an insulating layer 100 and a conductive layer 200 are sequentially stacked on a substrate 1, and the photolithography process is performed using a photomask 10 shown in FIG. 1G to form a patterned photoresist layer 300 corresponding to a pattern of the photomask 10 on the conductive layer 200. The photomask 10 includes multiple patterns 10C.

In the step shown in FIG. 1B, an etching process is performed. An area on the line segment AC is an etching area, corresponding to the pattern 10C shown in FIG. 1G. Accordingly, the patterned conductive layer 200 shown in FIG. 1C is formed. Therefore, the patterned conductive layer 200 in FIG. 1C has multiple patterns corresponding to the patterns 10C shown in FIG. 1G. It should be noted that although the patterns 10C in FIG. 1G are circular, the disclosure is not limited thereto. In some embodiments of the disclosure, there is no included angle less than or equal to 75 degrees on the patterns 10C.

In the step shown in FIG. 1D, the photolithography process is performed using a photomask 20 shown in FIG. 1H to form a patterned photoresist layer 400 corresponding to a pattern of the photomask 20 on the insulating layer 100 and the patterned conductive layer 200. In the step shown in FIG. 1E, the etching process is performed, thereby generating an electronic device 1000 shown in FIG. 1F. The electronic device 1000 includes the substrate 1, the insulating layer 100, and a patterned conductive layer 200′.

The patterned conductive layer 200′ in FIG. 1F may be used as a wire in the manufactured electronic device 1000, and a top surface thereof away from the substrate 1 is higher than a top surface of the insulating layer 100. In addition, the insulating layer 100 corresponding to the line segment CE′, the line segment BC, and the line segment AB is not provided with the wire, which may be used as a light transmission area in the manufactured electronic device 1000, but the disclosure is not limited thereto. Through the above process, a top surface T1 of the partial insulating layer 100 (a first partial insulating layer) on the line segment CE′ will be higher than a top surface T2 of the partial insulating layer 100 (a second partial insulating layer) on the line segment BC relative to the substrate 1, and a top surface T3 of the partial insulating layer 100 (a third partial insulating layer) on the line segment AB will be higher than the top surface T2 of the partial insulating layer 100 (the second partial insulating layer) on the line segment BC relative to the substrate 1.

It should be noted that the photomask 20 shown in FIG. 1H includes a pattern 20C and a pattern 20D. The pattern 20C corresponds to the patterned photoresist layer 400 located on the insulating layer 100 in FIGS. 1D and 1E, and the pattern 20D corresponds to the patterned photoresist layer 400 located on the patterned conductive layer 200 in FIGS. 1D and 1E. By disposing the pattern 20C on the photomask 20 to form the patterned photoresist layer 400 on the insulating layer 100, a product in the process may be prevented from adhering to a surface of the insulating layer 100, which is beneficial to improving a yield of the subsequent processes.

It should also be noted that, for the convenience of understanding, the pattern 10C of the photomask 10 in the aforementioned process steps is also marked with a dashed line in FIG. 1H. Therefore, it may be seen that a diameter of the pattern 20C of the photomask 20 is less than a diameter of the pattern 10C of the photomask 10. In addition, although the patterns 20C in FIG. 1H are circular, the disclosure is not limited thereto. In some embodiments of the disclosure, there is no included angle less than or equal to 75 degrees on the patterns 20C. In other words, there is no included angle less than or equal to 75 degrees on the patterned photoresist layer 400 corresponding to the pattern 20C formed in the step shown in FIG. 1D.

Referring to both FIGS. 1E and 1H, since the patterned photoresist layer 400 (FIG. 1E) on the insulating layer 100 corresponds to the pattern 20C (FIG. 1H) and has a gap between it and the patterned conductive layer 200, and the gap corresponds to the line segment BC, the top surface T2 of the partial the insulating layer 100 (the second partial insulating layer) on the line segment BC is formed into a concave surface during the etching process (as shown in FIG. 1F). In addition, as mentioned above, the patterned conductive layer 200 has a pattern corresponding to the pattern 10C (FIG. 1G). Therefore, in a top view, the top surface T2 shown in FIG. 1F will be formed into an annular pattern corresponding to the pattern 10C and the pattern 20C shown in FIG. 1H. In other words, a vertical projection of the top surface T2 on the substrate 1 will be formed into an annular pattern. The annular pattern includes a first outline corresponding to the pattern 20C and a second outline corresponding to the pattern 10C. The first outline is surrounded by the second outline, and there is no included angle less than or equal to 75 degrees on the first outline and the second outline. In some embodiments, the first outline and the second outline are conformal. For example, both the outlines are circular, but the disclosure is not limited thereto. In some embodiments, the first outline and the second outline may not be conformal. For example, one outline is circular, and the other outline is hexagonal.

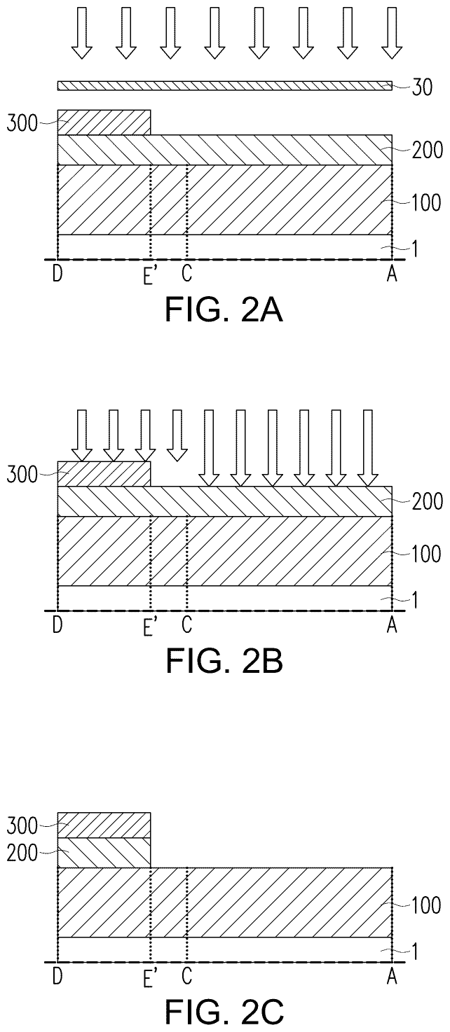

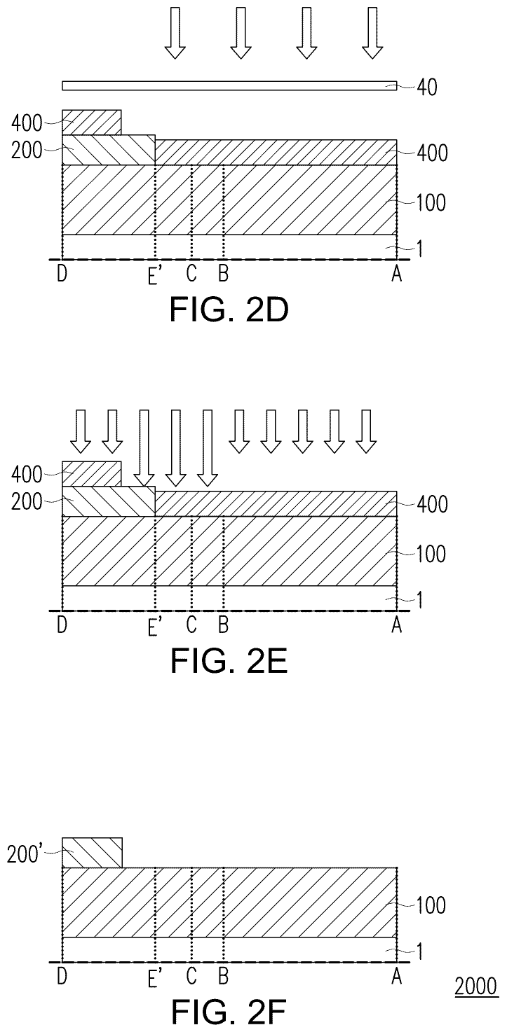

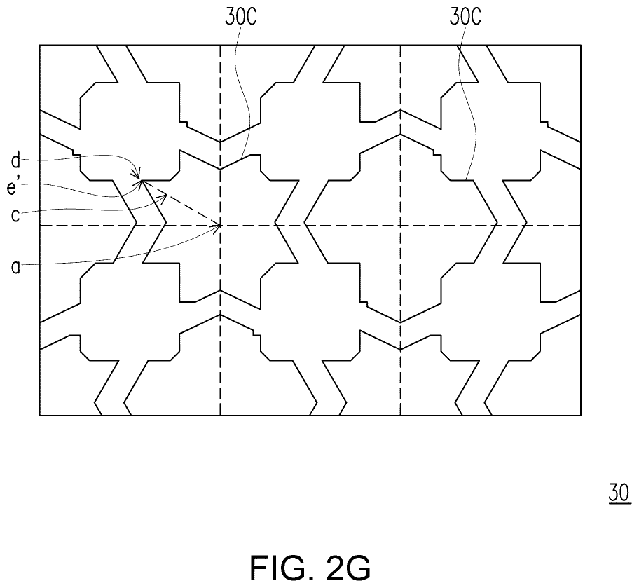

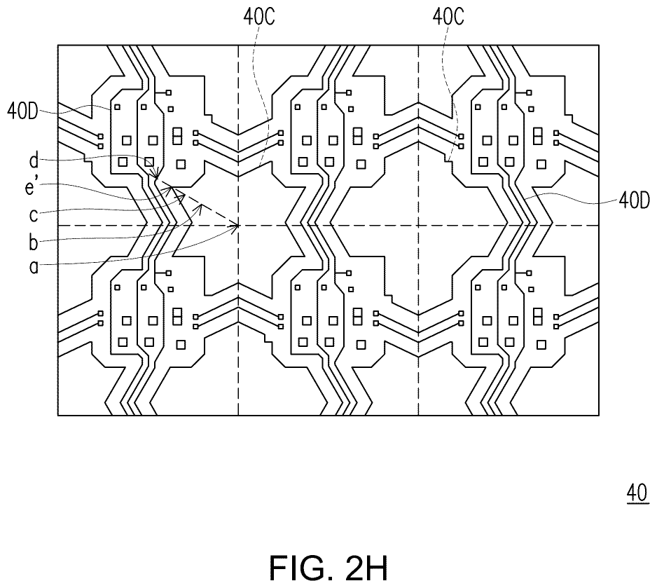

FIGS. 2A to 2F are schematic views of a manufacturing method of an electronic device according to a comparative example. FIG. 2G is a schematic view of a photomask in a photolithography process shown in FIG. 2A. The cross-section line AD in FIG. 2A is a straight line formed by the three line segments of the line segment AC, the line segment CE′, and the line segment E′D. FIG. 2G shows a dashed line corresponding to the cross-section line AD in FIG. 2A, and the positions a, c, e′, and d respectively corresponding to the endpoints A, C, E′, and D of the line segments in FIG. 2A are correspondingly marked thereon. FIG. 2H is a schematic view of a photomask in a photolithography process shown in FIG. 2D. The cross-section line AD in FIG. 2D is a straight line formed by the four line segments of the line segment AB, the line segment BC, the line segment CE′, and the line segment E′D. FIG. 2H shows a dashed line corresponding to the cross-section line AD in FIG. 2D, and the positions a, c, e′, and d corresponding to the endpoints A, C, E′, and D of the line segments in FIG. 2D are correspondingly marked thereon.

In the step shown in FIG. 2A, the insulating layer 100 and the conductive layer 200 are sequentially stacked on the substrate 1, and the photolithography process is performed using a photomask 30 shown in FIG. 2G to form the patterned photoresist layer 300 corresponding to a pattern of the photomask 30 on the conductive layer 200. The photomask 30 includes multiple patterns 30C.

In the step shown in FIG. 2B, the etching process is performed. An area on a line segment AE′ is an etching area, corresponding to the pattern 30C shown in FIG. 2G. Accordingly, the patterned conductive layer 200 shown in FIG. 2C is formed. Therefore, the patterned conductive layer 200 in FIG. 2C has multiple patterns corresponding to the patterns 30C shown in FIG. 2G. It should be noted that there are multiple included angles less than or equal to 75 degrees on the patterns 30C, such as a position e′.

In the step shown in FIG. 2D, the photolithography process is performed using a photomask 40 shown in FIG. 2H to form the patterned photoresist layer 400 corresponding to a pattern of the photomask 40 on the insulating layer 100 and the patterned conductive layer 200. The photomask 40 shown in FIG. 2H includes a pattern 40C and a pattern 40D. the pattern 40C corresponds to the patterned photoresist layer 400 located on the insulating layer 100 in FIGS. 2D and 2E, and the pattern 40D corresponds to the patterned photoresist layer 400 located on the patterned conductive layer 200 in FIGS. 2D and 2E.

In the step shown in FIG. 2E, the etching process is performed, thereby generating an electronic device 2000 shown in FIG. 2F. The electronic device 2000 includes the substrate 1, the insulating layer 100, and the patterned conductive layer 200′. The patterned conductive layer 200′ may be used as a wire in the manufactured electronic device 2000.

However, it should be noted that since the pattern 30C (see FIG. 2G) has the included angle less than or equal to 75 degrees at the position e′, the patterned conductive layer 200 formed in the step shown in FIG. 2C will have an obtuse angle corresponding to the above-mentioned included angle. Further, when the patterned photoresist layer 400 is formed in the step shown in FIG. 2D, the patterned photoresist layer 400 will be formed into a structure with the included angle less than or equal to 75 degrees at a junction (corresponding to the endpoint E′) with the patterned conductive layer 200. In this way, the patterned photoresist layer 400 will be more difficult to adhere there and will be susceptible to water vapor intrusion. Under such a situation, the patterned photoresist layer 400 may be partially peeled off, further affecting the integrity of the patterned conductive layer 200′ formed in the step shown in FIG. 2F, and ultimately leading to wire breakage in the electronic device 2000. In contrast, in the implementation of the disclosure shown in FIGS. 1A to 1H, there is no structure on the patterns 10C and 20C that has the included angle less than or equal to 75 degrees. Therefore, issues of peeling of the photoresist layer and wire breakage that occurred in the comparative example may be avoided.

Based on the above, in the manufacturing method of the electronic device provided in the embodiment of the disclosure, the electronic device is manufactured using two yellow light process phases to improve a shape of the patterned photoresist layer, so as to avoid the issues of peeling of the photoresist layer and wire breakage, greatly improving the yield of the electronic device.

What is claimed is:

1. An electronic device, comprising a substrate, an insulating layer, and a conductive layer that are sequentially stacked, wherein
the insulating layer comprises a first portion, a second portion, and a third portion, the second portion is located on a side of the first portion away from the conductive layer, the third portion is located on a side of the second portion away from the conductive layer, and the first portion, the second portion, and the third portion are sited in a connection manner,
a top surface of the conductive layer away from the substrate is higher than a top surface of the insulating layer, a top surface of the first portion is higher than a top surface of the second portion, and a top surface of the third portion is higher than the top surface of the second portion.

2. The electronic device according to claim 1, wherein a vertical projection of the top surface of the second portion on the substrate is formed into an annular pattern.

3. The electronic device according to claim 2, wherein the annular pattern comprises a first outline and a second outline, the first outline is surrounded by the second outline, and the first outline and the second outline are conformal.

4. The electronic device according to claim 2, wherein the annular pattern comprises a first outline and a second outline, the first outline is surrounded by the second outline, and the first outline and the second outline are not conformal.

5. The electronic device according to claim 2, wherein the annular pattern comprises a first outline and a second outline, the first outline is surrounded by the second outline, and there is no included angle less than or equal to 75 degrees on the first outline and the second outline.

6. The electronic device according to claim 1, wherein the conductive layer is not disposed on the first portion, the second portion, and the third portion.

7. A manufacturing method of an electronic device, comprising:
sequentially stacking an insulating layer and a conductive layer on a substrate;
forming a first patterned photoresist layer using a first photomask;
corresponding to a pattern of the first patterned photoresist layer, removing a portion of the conductive layer to expose the insulating layer;
forming a second patterned photoresist layer using a second photomask, wherein the second patterned photoresist layer exposes a portion of the insulating layer; and
removing the portion of the insulating layer.

8. The manufacturing method of the electronic device according to claim 7, further comprising:
forming an annular pattern on a top surface of the insulating layer away from the substrate.

9. The manufacturing method of the electronic device according to claim 8, wherein the annular pattern comprises a first outline and a second outline, the first outline is surrounded by the second outline, and there is no included angle less than or equal to 75 degrees on the first outline and the second outline.

10. The manufacturing method of the electronic device according to claim 8, wherein the annular pattern comprises a first outline and a second outline, the first outline is surrounded by the second outline, and the first outline and the second outline are conformal.

11. The manufacturing method of the electronic device according to claim 8, wherein the annular pattern comprises a first outline and a second outline, the first outline is surrounded by the second outline, and the first outline and the second outline are not conformal.
